(19) United States
(12) Patent Application Publication
(10) Pub. No.: US 2011/0220865 A1
(43) Pub. Date: Sep. 15, 2011

(54) TRANSISTOR AND MANUFACTURING METHOD THEREOF

(75) Inventors: Toshitaka Miyata, Kanagawa-ken (JP); Kanna Adachi, Kanagawa-ken (JP); Shigeru Kawanaka, Kanagawa-ken (JP); Shu Nakaharai, Ibaraki-ken (JP)

(73) Assignee: KABUSHIKI KAISHA TOSHIBA, Tokyo (JP)

(21) Appl. No.: 13/044,727

(22) Filed: Mar. 10, 2011

(30) Foreign Application Priority Data
Mar. 11, 2010 (JP) 2010-54853

(51) Int. Cl. H01L 29/66; B82Y 99/00

(52) U.S. Cl. 257/12; 257/9; 977/734; 257/E29.168

(57) ABSTRACT

According to an embodiment of the present invention, a transistor includes a source electrode, a drain electrode, a graphene film formed between the source electrode and the drain electrode and having a first region and a second region, and a gate electrode formed on the first region and the second region of the graphene film via a gate insulating film. The graphene film functions as a channel. A Schottky junction is formed at a junction between the first region and the second region. The first region has a conductor property, and the second region is adjacent to the drain electrode side of the first region and has a semiconductor property.

### CROSS-REFERENCE TO RELATED APPLICATION

This application is based upon and claims the benefit of priority from prior Japanese Patent Application No. 2010-54853, filed on Mar. 11, 2010, the entire contents of which are incorporated herein by reference.

### FIELD

Embodiments of the present invention relate to a transistor and a manufacturing method thereof.

### BACKGROUND

As a conventional transistor, a transistor that has a channel made of two layers of a graphene film, and applies a voltage to the graphene film in a vertical direction to generate a band gap for executing a switching operation is known.

A transistor that includes graphene have a one-dimensional structure called a graphene nanoribbon, generates a band gap using a quantum confinement effect or a graphene edge effect, and executes a switching operation is also known.

However, in the above transistors, since the generated band gap is small, a cutoff characteristic may be deteriorated.

An influence on an electronic characteristic of the graphene by the oxidation treatment is reported. According to this report, the magnitude of the band gap is changed according to an oxidation state of the graphene. Specifically, as an oxidation level of the graphene is higher and the amount of oxygen (O or OH) coupled to a surface is larger, the magnitude of the band gap increases.

### BRIEF DESCRIPTION OF THE DRAWINGS

FIG. 1 is a cross-sectional view of a transistor according to a first embodiment of the present invention;

FIG. 2 is a top view of a graphene film according to the first embodiment;

FIG. 3 is diagram schematically showing a band structure of the graphene film according to the first embodiment;

FIGS. 4A to 4F are cross-sectional views showing manufacturing processes of the transistor according to the first embodiment;

FIG. 5 is a cross-sectional view of a transistor according to a second embodiment of the present invention;

FIG. 6 is a top view of a graphene film according to the second embodiment;

FIG. 7 is diagram schematically showing a band structure of the graphene film according to the second embodiment;

FIG. 8 is a top view of a graphene film according to a comparative example;

FIG. 9 is diagram schematically showing a band structure of the graphene film according to the comparative example; and

FIG. 10 is diagrams schematically showing a band structure of a graphene film according to another comparative example.

### DETAILED DESCRIPTION

In one embodiment of the present invention, a transistor includes a source electrode; a drain electrode; a graphene film formed between the source electrode and the drain electrode and having a first region and a second region and functioning as a channel, a Schottky junction being formed at a junction between the first region and the second region; and a gate electrode formed on the first region and the second region of the graphene film via a gate insulating film. The first region has a conductor property, and the second region is adjacent to the drain electrode side of the first region and has a semiconductor property.

### First Embodiment

### Configuration of a Semiconductor Device

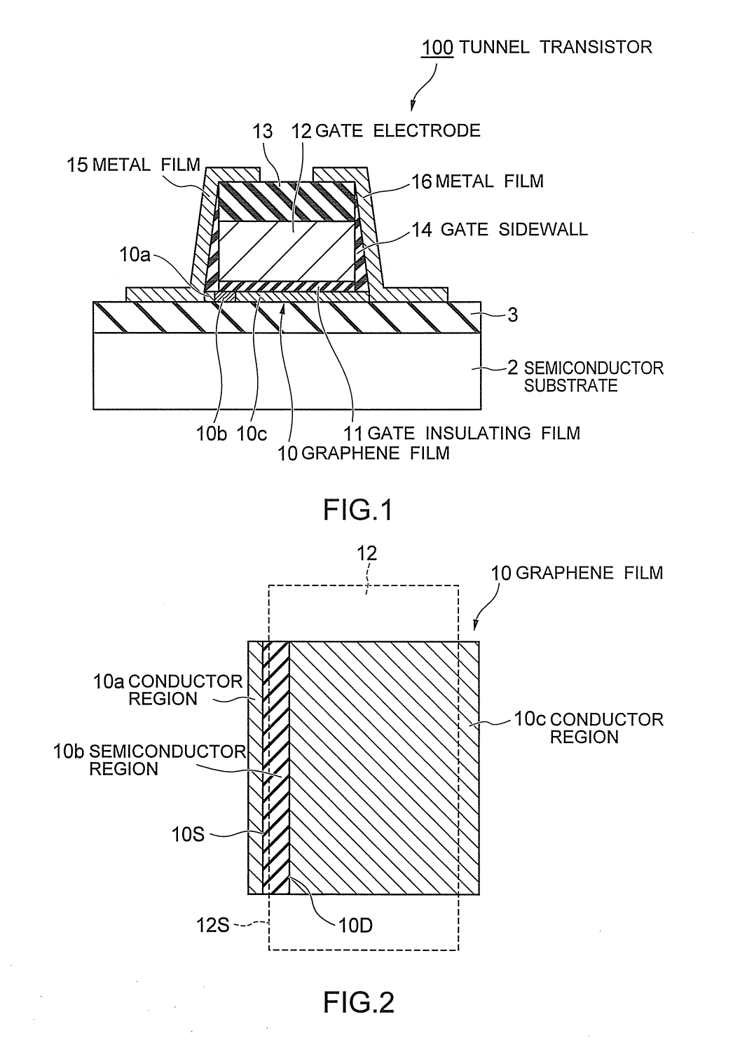

FIG. 1 is a cross-sectional view of a transistor 100 according to the first embodiment of the present invention. The transistor 100 uses a tunnel current passing through a Schottky barrier, when a switching operation is executed.

The transistor 100 includes a semiconductor substrate 2, an insulating film 3 that is formed on the semiconductor substrate 2, a graphene film 10 that functions as a channel formed on the insulating film 3, a gate electrode 12 that is formed on the graphene film 10 through a gate insulating film 11, a cap film 13 that is formed on the gate electrode 12, a gate sidewall 14 that is formed on a side of the gate electrode 12, a metal film 15 that is connected to a source-side end of the graphene film 10, and a metal film 16 that is connected to a drain-side end of the graphene film 10.

For example, a semiconductor substrate made of Si crystal is used for the semiconductor substrate 2.

The insulating film 3 is made of an insulating material such as SiO₂.

The gate insulating film 11 is made of an insulating material such as SiO₂, SiN, and SiON or a high-permittivity material such as HfSiON.

The gate electrode 12 is made of, for example, a Si polycrystalline material such as polycrystalline Si including conductive impurities, a metal or a laminator thereof.

The cap film 13 is made of an insulating material such as SiN.

The gate sidewall 14 is made of an insulating material such as SiO₂ and SiN.

The metal film 15 that functions as a source electrode and the metal film 16 that functions as a drain electrode are made of a metal such as Pd.

The graphene film 10 is made of a graphene sheet of one to several tens of layers, and has a ballistic conduction characteristic. In this case, the graphene sheet is a single-layered film made of graphite.

FIG. 2 is a top view of the graphene film 10. In FIG. 2, a dotted line shows the position of the gate electrode 12 on the graphene film 10. The graphene film 10 has conductor regions 10a and 10c and a semiconductor region 10b.

The semiconductor region 10b is a region of the graphene film 10 on which reforming treatment is performed. Examples of the reforming treatment include oxidation treatment that couples oxygen to a surface of the graphene film 10, nitridation treatment that couples nitrogen to the surface, and hydrotreatment that couples hydrogen to the surface.

A band gap exists in the semiconductor region 10b and the semiconductor region 10b has a semiconductor property. For example, the band gap is generated in the semiconductor region 10b because the positions of C atoms of the graphene film 10 to which atoms such as oxygen are coupled are shifted and unevenness is generated in the graphene sheet constituting the graphene film 10. In the present embodiment, graphene that has a band gap of more than 10 meV is called graphene that has a semiconductor property.

The semiconductor region 10b is preferably positioned below the source-side end 12S of the gate electrode 12. That is, the source-side end 10S of the semiconductor region 10b is preferably positioned right below the source-side end 12S or closer to the source side (left side of FIG. 2) than the source-side end 12S, and the drain-side end 10D of the semiconductor region 10b is preferably positioned right below the source-side end 12S or closer to the drain side (right side of FIG. 2) than the source-side end 12S.

The conductor regions 10a and 10c are conductor regions that are separated by the semiconductor region 10b in a channel direction, and a source-side region is the conductor region 10a and a drain-side region is the conductor region 10c. The conductor regions 10a and 10c are regions on which the reforming treatment are not performed, and exhibit the original conductor property of the graphene. In the present embodiment, graphene that has a band gap of 10 meV or less and graphene that does not have a band gap are called graphene that has a conductor property.

The graphene film 10 may include only the conductor region 10a and the semiconductor region 10b. Alternatively, instead of the conductor region 10c, a region that has a band gap smaller than that of the semiconductor region 10b may be formed.

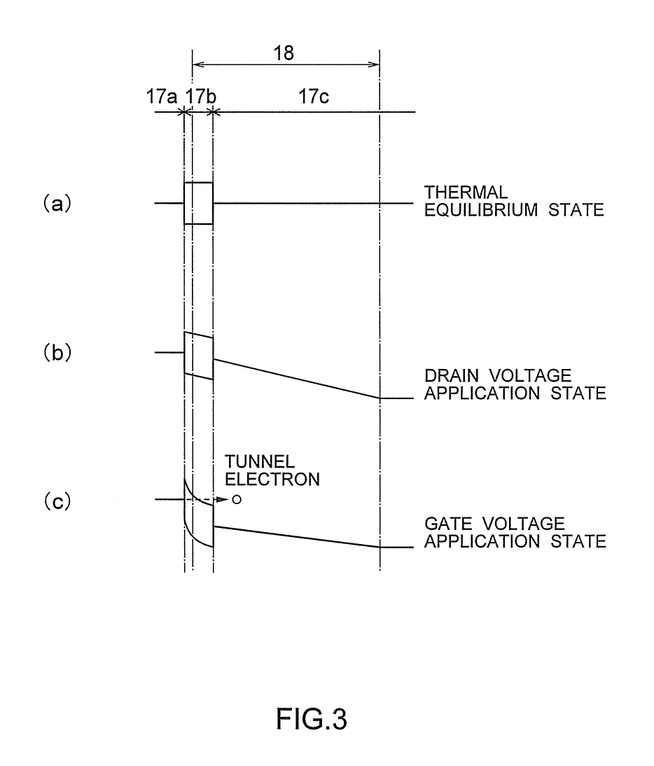

FIGS. 3A to 3C schematically show the band structure of the graphene film 10. In FIGS. 3A to 3C, a horizontal axis indicates the position of the channel direction (horizontal direction of FIG. 2).

The regions 17a, 17b, and 17c are regions of the conductor region 10a, the semiconductor region 10b, and the conductor region 10c in the channel direction, respectively. The region 18 is a region below the gate electrode 12.

Lines of the regions 17a and 17c indicate Fermi levels of the conductor regions 10a and 10c, an upper line of the region 17b indicates an energy level of a lower end of a conduction band of the semiconductor region 10b, and a lower line of the region 17b indicates an energy level of an upper end of a valence band of the semiconductor region 10b.

FIG. 3(a) shows a band structure of a thermal equilibrium state where a voltage is not applied to the transistor 100. Since a band gap exists in the region 17b, electrons do not move from the region 17a to the region 17c. FIG. 3 (a) shows a flat band state. However, if the electrons do not move between the region 17a and the region 17c, the thermal equilibrium state may not be the flat band state.

FIG. 3 (b) shows a band structure of a state where a drain voltage is applied. In this state, the source potential and the gate potential are set to ground (GND). By applying the drain voltage, energy levels of the conductor regions 10a and 10c and the semiconductor region 10b are declined. Even in this state, the electrons are suppressed from moving from the source to the drain by a Schottky barrier existing in the source-side end (in the vicinity of a boundary between the regions 17a and 17b) of the semiconductor region 10b, and the transistor 100 is in a cutoff state. The decline in the Fermi levels of the conductor regions 10a and 10c in a region outside of the region 18 is not shown in the drawings.

FIG. 3 (c) shows a band structure of a state where a drain voltage and a gate voltage are applied. By applying the gate voltage, an energy level of the region 18 is shifted in a downward direction of FIG. 3 (c). At this time, bending is generated in the energy band of the semiconductor region 10b and the electrons tunnel the Schottky barrier. The course of tunneling the Schottky barrier that is deformed in a triangular shape due to the bending of the band is called a Fowler-Nordheim (FN) tunnel.

The electrons that have tunneled the Schottky barrier pass through the conductor region 10c to move to the drain side. In this case, since the electrons have extraordinarily high mobility in the conductor region 10c, the electrons can move to the drain side at a high speed. Thereby, the transistor 100 can show a high current driving ability.

Since the mobility of the electrons in the conduction band of the conductor region 10c is higher than the mobility of the electrons in the conduction band of the semiconductor region 10b, the width of the semiconductor region 10b in a channel direction is preferably minimized in a range where a sufficient cutoff characteristic can be secured.

In the case where the position of the source-side end 10S of the semiconductor region 10b (position of a Schottky junction) is closer to the drain side (right side of FIG. 2) than the source-side end 12S of the gate electrode 12, bending of the energy band of the semiconductor region 10b when the gate voltage is applied decreases. For this reason, the source-side end 10S of the semiconductor region 10b is preferably right below the source-side end 12S of the gate electrode 12 or closer to the source side (left side of FIG. 2) than the source-side end 12S of the gate electrode 12.

In the case where the position of the drain-side end 10D of the semiconductor region 10b (position of a Schottky junction) is closer to the source side (left side of FIG. 2) than the source-side end 12S of the gate electrode 12, bending of the energy band of the semiconductor region 10b when the gate voltage is applied decreases due to the semiconductor region 10b being rarely affected by the electric field based on application of the gate voltage. For this reason, the drain-side end 10D of the semiconductor region 10b is preferably right below the source-side end 12S of the gate electrode 12 or closer to the drain side (right side of FIG. 2) than the source-side end 12S of the gate electrode 12.

As such, in a state where the gate voltage is not applied (OFF state), the electrons are suppressed from moving from the source to the drain by the Schottky barrier. In a state where the gate voltage is applied (ON state), a current flows from the source to the drain. By the switching operation using the Schottky junction, the transistor 100 has a high cutoff characteristic.

FIG. 3 shows a band structure in the case where the transistor 100 is an n-type transistor. However, even when the transistor 100 is a p-type transistor, the same switching operation can be executed by reversing the polarities of the drain voltage and the gate voltage.

Hereinafter, an example of a method for manufacturing the transistor 100 according to the first embodiment will be described.

### (Manufacturing of a Semiconductor Device)

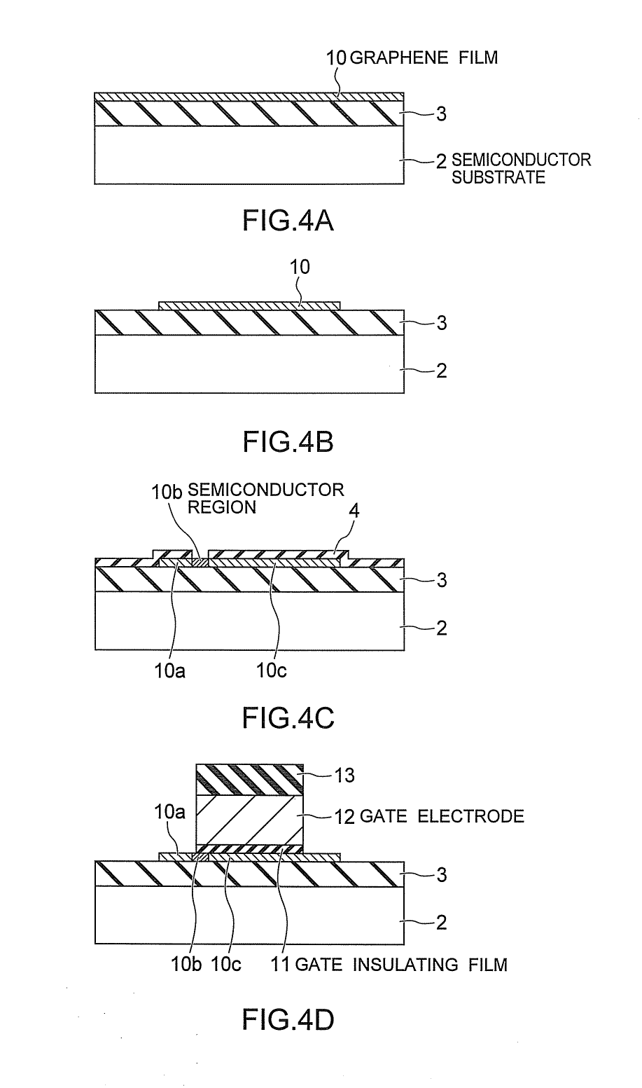

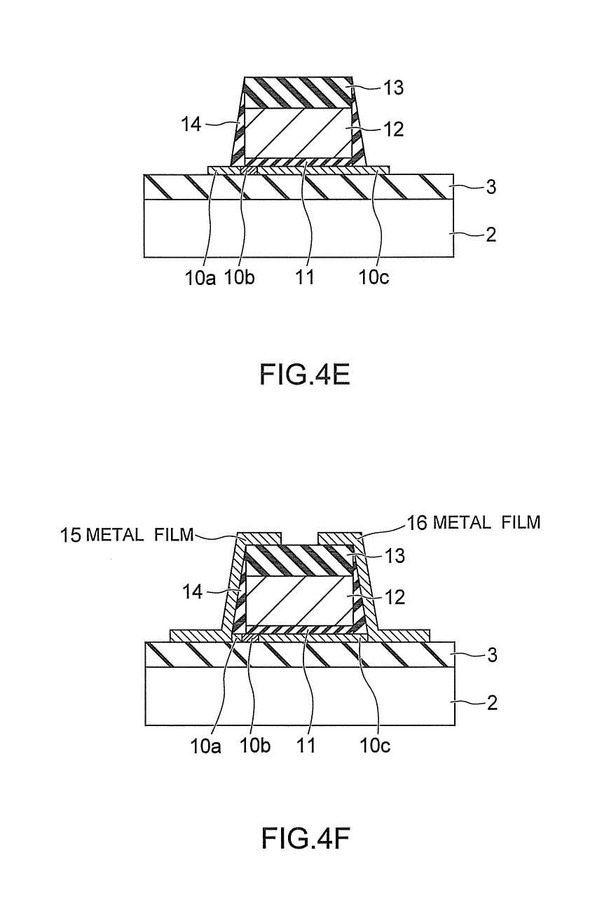

FIGS. 4A to 4F are cross-sectional views showing manufacturing processes of the transistor 100 according to the first embodiment of the present invention.

First, as shown in FIG. 4A, the insulating film 3 and the graphene film 10 are formed on the semiconductor substrate 2.

For example, by performing thermal oxidation on the surface of the semiconductor substrate 2, the SiO₂ film that has the thickness of 30 nm is formed as the insulating film 3. Next, the Si layer that has a thickness of 3 nm is formed on a surface of the insulating film 3 using a chemical vapor deposition (CVD) method, and fullerene is deposited thereon using a molecular beam epitaxial method (MBE) method. Subsequently, annealing treatment at 1000° C. is performed on the Si layer and the fullerene, under high vacuum, to form the SiC layer. Then, annealing treatment at 1200° C. is performed on the SiC layer, under high vacuum to obtain the graphene film 10.

Next, as shown in FIG. 4B, the graphene film 10 is patterned.

For example, the SiN film that has a thickness of 30 nm is formed on the graphene film 10 using the CVD method. Next, a resist pattern is formed on the SiN film by photolithography. Subsequently, etching is performed on the SiN film and the graphene film 10 using a reactive ion etching (RIE) method and the resist pattern is transferred. During this process, oxygen plasma is used in the etching of the graphene film 10. Then, the resist mask and the SiN film are removed.

Next, as shown in FIG. 4C, the insulating film 4 that has the pattern of the semiconductor region 10b as an opening pattern is formed on the graphene film 10, and the semiconductor region 10b is formed in the graphene film 10 by the deforming treatment such as the oxidation treatment using the insulating film 4 as a mask.

For example, the SiN film that has a thickness of 30 nm and functions as the insulating film 4 is formed on the graphene film 10 using the CVD method. Subsequently, the opening pattern of the pattern of the semiconductor region 10b is formed in the insulating film 4 using the photolithography and the RIE method. Then, the oxidation treatment is performed on a portion that is exposed in the opening pattern of the insulating film 4 of the graphene film 10 by heat oxidation, and the semiconductor region 10b is formed.

If an oxidation level is excessively high, the corresponding portion may become an insulator. For this reason, it is required to appropriately perform the oxidation treatment to obtain a semiconductor by controlling treatment conditions such as a treatment time. After the insulator is formed by the oxidation treatment, the semiconductor region 10b may be formed by lowering the oxidation level by the reduction treatment.

Next, as shown in FIG. 4D, after the insulating film 4 is removed, the gate insulating film 11, the gate electrode 12, and the cap film 13 are formed.

For example, an Al₂O₃ film that has a thickness of 3 nm is formed on the graphene film 10 and the insulating film 3 using the CVD method. During this process, preferably, deactivation treatment using NO₂ gas is performed on the surface of the graphene film 10 to prevent covalent bonding from being generated between the graphene film 10 and the Al₂O₃ film, before the Al₂O₃ film is formed. Next, a P-doped polycrystalline Si film that has a thickness of 50 nm is formed on the SiO₂ film using the CVD method. Subsequently, the SiN film that has a thickness of 30 nm is formed on the polycrystalline Si film using the CVD method. Then, using the resist where the gate pattern is formed by the photolithography as the mask, etching based on the RIE method is performed on the SiN film, the polycrystalline Si film, and the Al₂O₃ film, and the cap layer 13, the gate electrode 12, and the gate insulating film 11 are processed.

Next, as shown in FIG. 4E, the gate sidewall 14 is formed on the side of the gate electrode 12.

For example, the SiO₂ film that has the thickness of 5 nm is formed on the entire surface of the semiconductor substrate 2 using the CVD method.

Subsequently, anisotropic etching based on the RIE method is performed on the SiO₂ film, and the gate sidewall 14 is processed.

Next, as shown in FIG. 4F, the metal films 15 and 16 that are connected to the graphene film 10 are formed.

For example, a Pd film that has a thickness of 5 nm is formed on the entire surface of the semiconductor substrate 2 using a physical vapor deposition (PVD) method. Then, using a resist where a pattern of a contact electrode is formed by the lithography as a mask, etching based on the RIE method is performed on the Pd film, and the metal films 15 and 16 are processed.

The metal films 15 and 16 that are shown in FIG. 4F are formed after etching is performed on the graphene film 10 using the cap layer 13 and the gate sidewall 14 as a mask. However, the metal films 15 and 16 may be formed without performing the etching on the graphene film 10. Even in this case, since the current flows directly from the metal films 15 and 16 to the region of the graphene film 10 right below the gate sidewall 14, the switching operation of the transistor 100 rarely changes.

Then, although not shown in the drawings, contact plugs are connected to the gate electrode 12 and the metal films 15 and 16, respectively.

### (Effect According to the First Embodiment)

According to the first embodiment of the present invention, the Schottky junction of the conductor region 10a and the semiconductor region 10b of the graphene film 10 is used in the switching operation. Therefore, the transistor 100 can show a high current driving ability and a high cutoff characteristic.

### Second Embodiment

A second embodiment is different from the first embodiment in that an insulator region is formed instead of the semiconductor region 10b, and a semiconductor region is formed instead of the conductor regions 10a and 10c. The description of the same contents as those of the first embodiment is simplified or not repeated.

### (Configuration of a Semiconductor Device)

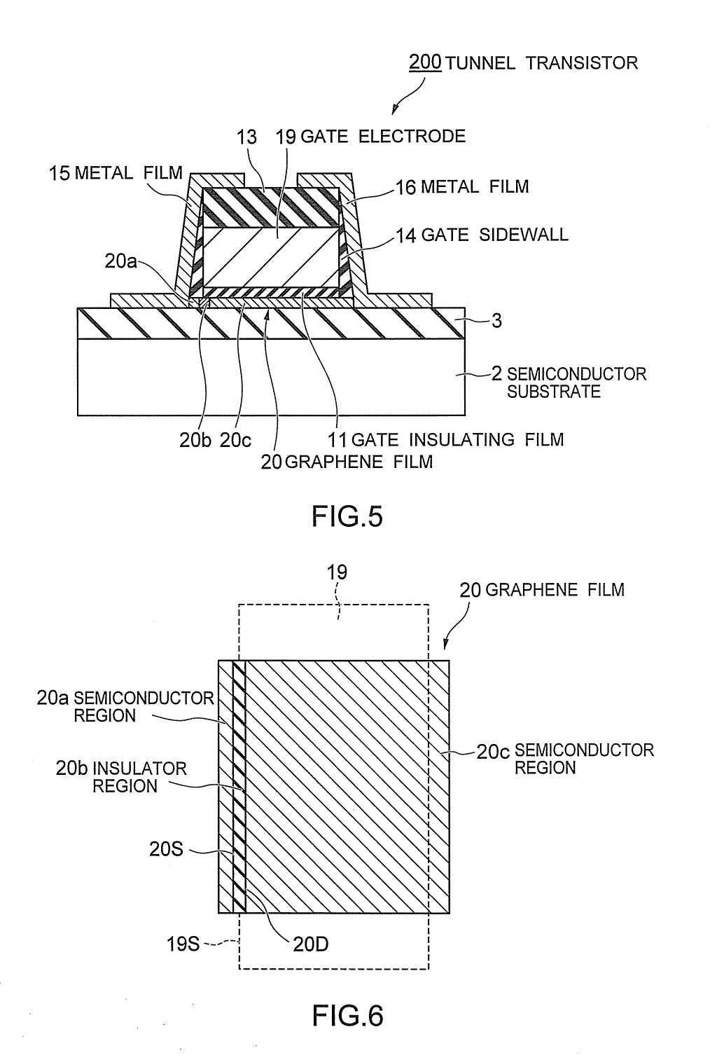

FIG. 5 is a cross-sectional view of a transistor 200 according to a second embodiment of the present invention. The transistor 200 uses a direct tunnel current passing through a band gap of an insulator region, when a switching operation is executed.

The transistor 200 includes a semiconductor substrate 2, an insulating film 3 that is formed on the semiconductor substrate 2, a graphene film 20 that functions as a channel formed on the insulating film 3, a gate electrode 19 that is formed on the graphene film 20 through the gate insulating film 11, a cap film 13 that is formed on the gate electrode 19, a gate sidewall 14 that is formed on a side of the gate electrode 19, a metal film 15 that is connected to a source-side end of the graphene film 20, and a metal film 16 that is connected to a drain-side end of the graphene film 20.

FIG. 6 is a top view of the graphene film 20. In FIG. 6, a dotted line shows the position of the gate electrode 19 on the graphene film 20. The graphene film 20 has semiconductor regions 20a and 20c and an insulator region 20b.

The insulator region 20b is a region of the graphene film 20 on which reforming treatment is performed. Examples of the reforming treatment include oxidation treatment that couples oxygen to a surface of the graphene film 20, nitridation treatment that couples nitrogen to the surface, and hydrotreatment that couples hydrogen to the surface.

A reforming level of the reforming treatment that is performed to form the insulator region 20b is higher than a reforming level of the reforming treatment that is performed to form the semiconductor region 10b according to the first embodiment. For example, when the oxidation treatment is used as the reforming treatment, the amount of oxygen that is coupled to the surface of the insulator region 20b is more than the amount of oxygen that is coupled to the surface of the semiconductor region 10b according to the first embodiment. When the nitridation treatment is used as the reforming treatment, the amount of nitrogen that is coupled to the surface of the insulator region 20b is more than the amount of nitrogen that is coupled to the surface of the semiconductor region 10b according to the first embodiment. When the hydrotreatment is used as the reforming treatment, the amount of hydrogen that is coupled to the surface of the insulator region 20b is more than the amount of hydrogen that is coupled to the surface of the semiconductor region 10b according to the first embodiment.

The insulator region 20b is preferably positioned below the source-side end 19S of the gate electrode 19. That is, the source-side end 20S of the insulator region 20b is preferably positioned right below the source-side end 19S or closer to the source side (left side of FIG. 6) than the source-side end 19S, and the drain-side end 20D of the insulator region 20b is preferably positioned below the source-side end 19S or closer to the drain side (right side of FIG. 6) than the source-side end 19S.

The semiconductor regions 20a and 20c are semiconductor regions that are separated by the insulator region 20b in a channel direction, and a source-side region is the semiconductor region 20a and a drain-side region is the semiconductor region 20c. The semiconductor regions 20a and 20c are formed by, for example, the same oxidation treatment as that used in the semiconductor region 10b according to the first embodiment. By decreasing the width of the graphene film 20 in a channel width direction and generating the band gap, the semiconductor regions 20a and 20c may be formed.

A work function of the gate electrode 19 is less than that of the semiconductor region 20c of the graphene film 20. For this reason, an energy level of the region of the semiconductor region 20c below the gate electrode 19 increases. The work function of the gate electrode 19 can be adjusted by selecting a material or adjusting the concentration of introduced conductive impurities.

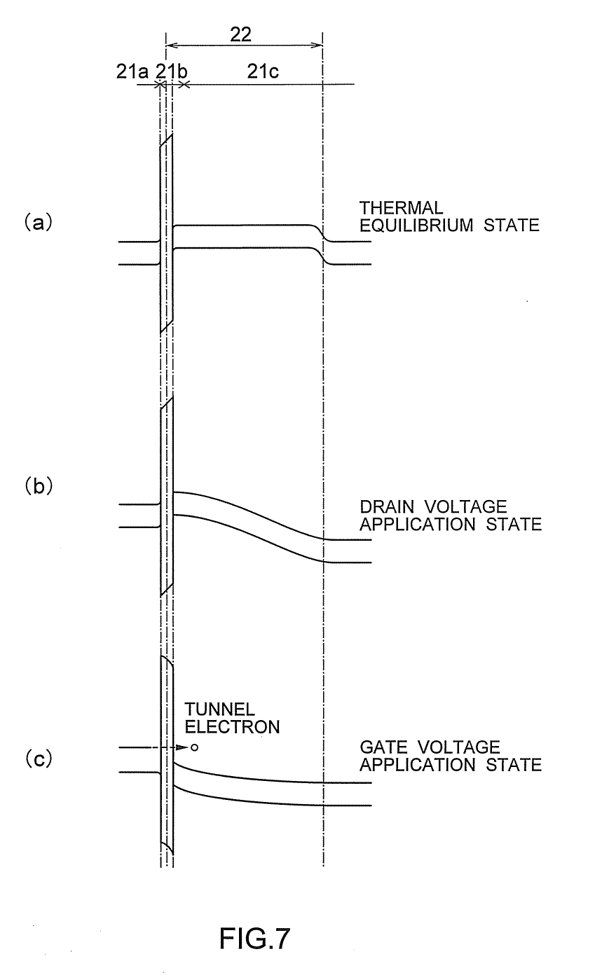

FIG. 7 schematically shows a band structure of the graphene film 20. In FIG. 7, a horizontal axis indicates the position of the channel direction (horizontal direction of FIG. 6).

The regions 21a, 21b, and 21c are regions of the semiconductor region 20a, the insulator region 20b, and the semiconductor region 20c in the channel direction, respectively. The region 22 is a region below the gate electrode 19.

Upper lines of the regions 21a, 21b, and 21c indicate energy levels of lower ends of conduction bands of the semiconductor region 20a, the insulator region 20b, and the semiconductor region 20c, respectively, and lower lines of the regions 21a, 21b, and 21c indicate energy levels of upper ends of valence bands of the semiconductor region 20a, the insulator region 20b, and the semiconductor region 20c, respectively.

FIG. 7 (a) shows a band structure of a thermal equilibrium state where a voltage is not applied to the transistor 200. Due to the difference of the work functions of the gate electrode 19 and the semiconductor region 20c, the difference exists in the energy level of the region 21a and the energy level of the region 21c in the region 22. Due to the difference of the energy levels, the energy gap, and the band gap of the region 21b, electrons do not move from the region 21a to the region 21c.

FIG. 7 (b) shows a band structure of a state where a drain voltage is applied. At this time, the source potential and the gate potential are set to GND. By applying the drain voltage, an energy level of the semiconductor region 20c is declined. Even in this state, the electrons are suppressed from moving from the region 21a to the region 21c, due to the difference of the energy levels of the regions 21a and 21c and the band gap of the region 21b. Accordingly, the transistor 200 is in a cutoff state. The decline in the energy bands of the semiconductor regions 20a and 20c in the outside region of the region 22 is not shown in the drawings.

FIG. 7 (c) shows a band structure of a state where a drain voltage and a gate voltage are applied. By applying the gate voltage, an energy level of the region 22 is shifted in a downward direction of FIG. 7 (c). For this reason, the energy level of the lower end of the conduction band of the region 21c becomes lower than the energy level of the lower end of the conduction band of the region 21a, and the electrons tunnel the band gap of the region 21b and move to the drain side.

The electrons that have tunneled the band gap of the region 21b pass through the semiconductor region 20c and move to the drain side. In this case, since the electrons have extraordinarily high mobility in the semiconductor region 20c, the electrons can move to the drain side at a high speed. Thereby, the transistor 200 can show a high current driving ability.

FIG. 7 shows a band structure in the case where the transistor 200 is an n-type transistor. However, even when the transistor 200 is a p-type transistor, the same switching operation can be executed by reversing the polarities of the drain voltage and the gate voltage.

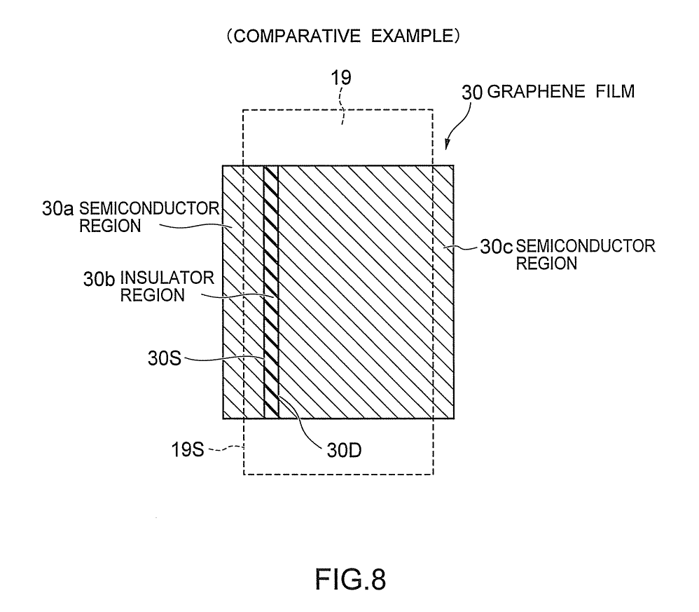

FIG. 8 is a top view of a graphene 30 according to a comparative example of the graphene 20. The graphene 30 is different from the graphene 20 in the position of the insulator region.

The insulator region 30b is a region of the graphene film 30 on which the reforming treatment such as the oxidation treatment is performed. A band gap exists in the insulator region 30a and the insulator region 30a has an insulator property. The source-side end 30S of the insulator region 30b is positioned closer to the drain side than the source-side end 19S of the gate electrode 19.

The semiconductor regions 30a and 30c are semiconductor regions that are separated by the insulator region 30b in a channel direction, and a source-side region is the semiconductor region 30a and a drain-side region is the semiconductor region 30c.

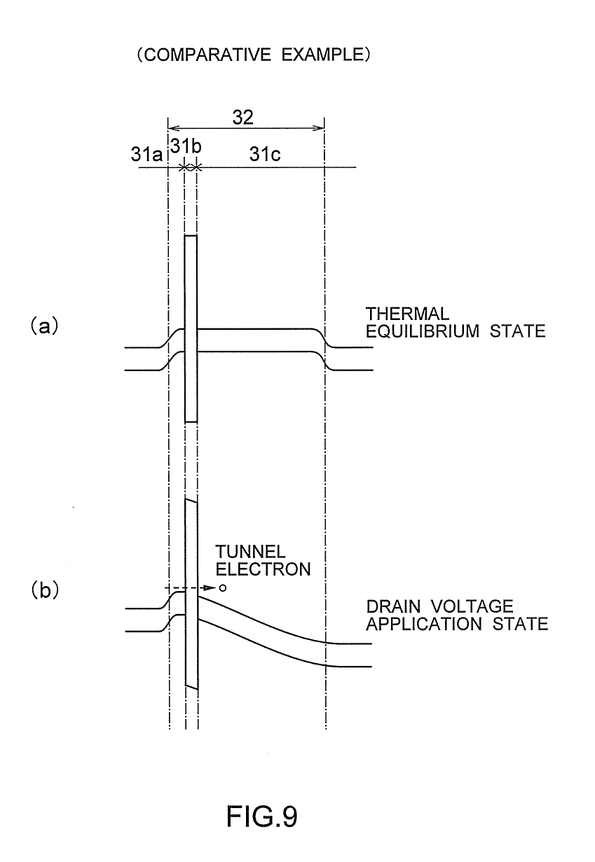

FIG. 9 schematically shows a band structure of the graphene film 30. In FIG. 9, a horizontal axis indicates the position of the channel direction (horizontal direction of FIG. 8).

The regions 31a, 31b, and 31c are regions of the semiconductor region 30a, the insulator region 30b, and the semiconductor region 30c in the channel direction, respectively. The region 32 is a region below the gate electrode 19.

FIG. 9(a) shows a band structure of a thermal equilibrium state where a voltage is not applied to the transistor 200. Due to the difference of the energy levels in the region 31a, the electrons do not move from the region 31a to the region 31c.

FIG. 9 (b) shows a band structure of a state where a drain voltage is applied. By applying the drain voltage, an energy level of the semiconductor region 30c is declined. At this time, since the difference of the energy levels of the lower ends of the conduction bands in the region 31a decreases, the electrons easily become beyond the difference of the energy levels.

The electrons that become beyond the difference of the energy levels of the lower ends of the conduction bands in the region 31a tunnel the band gap of the region 31b and move to the drain side.

As such, when the source-side end 30S of the insulator region 30b is positioned closer to the drain side than the source-side end 19S of the gate electrode 19, the current may flow from the source to the drain in an OFF state where the gate voltage is not applied.

For this reason, the source-side end 20S of the insulator region 20b according to the second embodiment is preferably positioned right below the source-side end 19S of the gate electrode 19 or closer to the source side than the source-side end 19S of the gate electrode 19.

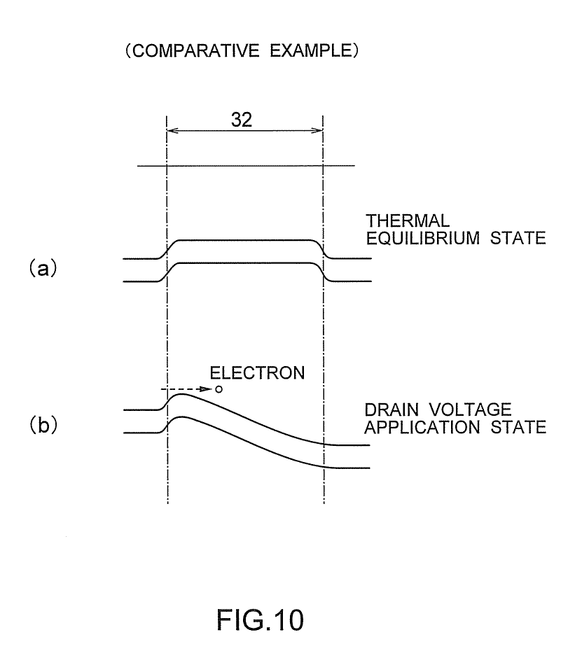

FIG. 10 schematically shows a band structure in the case where the insulator region 30b is not formed in the graphene film 30. In FIG. 10, each horizontal axis indicates the position of the channel direction.

FIG. 10 (a) shows a band structure of a thermal equilibrium state where a voltage is not applied to the transistor 200. Due to the difference of the energy levels, the electrons do not move from the source to the drain.

FIG. 10 (b) shows a band structure of a state where a drain voltage is applied. By applying the drain voltage, the difference of the energy levels of the lower ends of the conduction bands decreases. For this reason, the electrons easily become beyond the difference. The electrons that become beyond the difference of the energy levels of the lower ends of the conduction bands in the region 31a move to the drain side.

As such, when the insulator region 30b is not formed, the current may flow from the source to the drain in an OFF state where the gate voltage is not applied.

When the source-side end 30D of the insulator region 30b is positioned closer to the source side than the source-side end 19S of the gate electrode 19, the insulator region 30b is rarely affected by the electric field based on application of the gate voltage. For this reason, similar to the case where the insulator region 30b is not formed, the current may flow from the source to the drain in an OFF state.

Therefore, the drain-side end 20D of the insulator region 20b according to the second embodiment is preferably positioned right below the source-side end 19S of the gate electrode 19 or closer to the drain side than the source-side end 19S of the gate electrode 19.

### (Effect According to the Second Embodiment)

According to the second embodiment of the present invention, the difference of the energy levels of the conductor region 20a and the conductor region 20c, the energy gap, and the band gap of the insulator region 20b are used in the switching operation. Therefore, the transistor 200 can show a high current driving ability and a high cutoff characteristic.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A transistor, comprising:
a source electrode;
a drain electrode;
a graphene film formed between the source electrode and the drain electrode and having a first region and a second region and functioning as a channel, a Schottky junction being formed at a junction between the first region and the second region; and
a gate electrode formed on the first region and the second region of the graphene film via a gate insulating film,
wherein the first region has a conductor property, and the second region is adjacent to the drain electrode side of the first region and has a semiconductor property.

2. The transistor according to claim 1, wherein the second region has a band gap of 10 meV or more.

3. The transistor according to claim 1, wherein a source-side end of the second region is positioned right below a source-side end of the gate electrode or closer to the source electrode side than the source-side end of the gate electrode.

4. The transistor according to claim 1, wherein a drain-side end of the second region is positioned right below a source-side end of the gate electrode or closer to the drain electrode side than the source-side end of the gate electrode.

5. The transistor according to claim 1, wherein the second region of the grapheme firm has atoms including at least one of oxygen atoms, nitrogen atoms, and hydrogen atoms.

6. The transistor according to claim 1, wherein the source electrode and the drain electrode are metal films connected to a source-side end and a drain-side end of the graphene film, respectively.

7. The transistor according to claim 1, further comprising a cap film provided on the gate electrode.

8. The transistor according to claim 1, wherein the graphene film further has a third region that is adjacent to the drain electrode side of the second region and has a conductor property.

9. The transistor according to claim 8, wherein the gate electrode is also formed on the third region of the graphene film.

10. The transistor according to claim 1, wherein the graphene film further has a third region, the third region being adjacent to the drain electrode side of the second region and having a band gap smaller than a band gap of the second region.

11. The transistor according to claim 10, wherein the gate electrode is also formed on the third region of the graphene film.

12. A transistor, comprising:
a source electrode;
a drain electrode;
a graphene film formed between the source electrode and the drain electrode and having a first region, a second region, and a third region and functioning as a channel; and
a gate electrode made of a material having a work function smaller than a work function of a material of the third region and formed on the graphene film through a gate insulating film,
wherein the first region has a semiconductor property; the second region is adjacent to the drain electrode side of the first region and has an insulator property; and the third region is adjacent to the drain electrode side of the second region and has a semiconductor property.

13. The transistor according to claim 12, wherein the first and third regions have a band gap of 10 meV or more.

14. The transistor according to claim 12, wherein a source-side end of the second region is positioned right below a source-side end of the gate electrode or closer to the source electrode side than the source-side end of the gate electrode.

15. The transistor according to claim 12, wherein a drain-side end of the second region is positioned below a source-side end of the gate electrode or closer to the drain electrode side than the source-side end of the gate electrode.

16. The transistor according to claim 12, wherein the second region of the grephene film has the atoms including at least one of oxygen atoms, nitrogen atoms, and hydrogen atoms.

17. The transistor according to claim 12, wherein surfaces of the first and third regions are coupled to at least one of oxygen atoms, nitrogen atoms, and hydrogen atoms.

18. The transistor according to claim 12, wherein the source electrode and the drain electrode are metal films connected to a source-side end and a drain-side end of the graphene film, respectively.

19. The transistor according to claim 12, further comprising a cap film provided on the gate electrode.
